(19) United States
(12) Patent Application Publication
(10) Pub. No.: US 2026/0223516 A1
(43) Pub. Date: Jul. 30, 2026

(54) MICRO-DISPLAY CHIP AND METHOD FOR MANUFACTURING THE SAME AND DISPLAY PANEL

(71) Applicant: Hue Inc., Shanghai (CN)

(72) Inventor: Huangjian Song, Shanghai (CN)

(73) Assignee: Hue Inc., Shanghai (CN)

(21) Appl. No.: 19/455,719

(22) Filed: Jan. 21, 2026

(30) Foreign Application Priority Data
Jan. 24, 2025 (CN) 202510115793.X

(51) Int. Cl. H10H 29/855; H10H 29/01

(52) U.S. Cl. CPC H10H 29/8552; H10H 29/0363

(57) ABSTRACT

Disclosed herein is a micro-display chip including a light-emitting area and a non-light-emitting area, wherein the non-light-emitting area is arranged around the light-emitting area and includes a package layer, wherein the surface of the package layer includes a plurality of rough structures. Etching and roughening the surface of the package layer can reduce its reflectivity, so that the light emitted from the light-emitting area is diffusely reflected after being reflected by the outside and reaching the surface of the package area, which can effectively reduce the re-reflection of full-band light and improve the quality of image display.

### CROSS-REFERENCE TO RELATED APPLICATION

This application claims the priority benefit of China application serial no. 202510115793.X, filed on January 24, 2025. The entirety of the above-mentioned patent application is hereby incorporated by reference herein and made a part of this specification.

### BACKGROUND

### Technical Field

The present disclosure relates to the field of micro-LED technology, particularly relates to a micro-display chip and a method for manufacturing the same, and a display panel.

### Description of Related Art

Micro light emitting diode (Micro-LED) micro-display chip is a new type LED structure obtained by thin-filming, miniaturizing, and arraying the original LED structure, which integrates the arrayed micro level micro-LEDs on an active addressing drive panel to achieve the lighting and individual control of the micro-LEDs, thereby outputting the desired display image. Micro-LED micro-display panels formed by the micro-LED micro-display chips can be applied in numerous products such as AR glasses.

FIG. 1 illustrates a structural schematic diagram of an existing micro-LED micro-display panel, as shown in FIG. 1, the existing micro-LED micro-display panel 001 includes a micro-display chip 011, an outer frame 012, a connection line 013, and a connector 014, wherein the outer frame 012 is arranged around the micro-display chip 011, and one end of the connection line 013 is connected with the micro-display chip 011, and the other end is connected with the connector 014, and the connector 014 is used for connection with external compatible devices. As shown in the figure, the micro-display chip 011 includes a light-emitting area 0111 and a non-light-emitting area 0112 surrounding the light-emitting area 0111, and the non-light-emitting area 0112 has a metal layer. FIG. 2 is the light propagation path schematic diagram of the micro-LED micro-display panel applied to AR glasses in the embodiment shown in FIG. 1. As shown in FIG. 2, light emitted from the micro-LED micro-display panel 001 passes through the optical lens 002 and then reaches the optical waveguide lens 003, and it can be displayed in the display area of optical waveguide lens 003.

However, as shown in FIG. 2, in existing products, when light emitted from the micro-LED micro-display panel 001 reaches the optical waveguide lens 003, a part of the light will be reflected back to the non-light-emitting area 0112 on the micro-LED micro-display panel 001, and then be reflected through the metal layer on the non-light-emitting area 0112, and then enters the optical waveguide lens 003 again, thereby resulting in two imaging at different positions on the optical waveguide lens 003, the image formed after reflection by non-light-emitting area 0112 is also known as "ghost image", and the presence of "ghost image" will significantly reduce the quality of the display image.

### SUMMARY

Aiming at some or all of the problems in the prior art, the first aspect of the present disclosure provides a micro-display chip, which includes:

a light-emitting area; and

a non-light-emitting area arranged around the light-emitting area, and the non-light-emitting area includes a package layer, where a surface of the package layer includes a plurality of rough structures.

Furthermore, the package layer is made of a solid plastic material.

Furthermore, the material of the package layer includes epoxy resin.

Furthermore, the rough structures are nanoparticles, and the average diameter of the nanoparticles is not more than 1 micrometer.

Furthermore, the reflectivity of the surface of the package layer having the rough structures is not greater than 0.5%.

Furthermore, the periphery of the light-emitting area has a shielding layer, and the package layer is located on the surface of or above the shielding layer.

Furthermore, the sidewall of the package layer close to the light-emitting area does not extend beyond the sidewall of the shielding layer close to the light-emitting area, so that the surface of the shielding layer close to the light-emitting area is exposed.

Furthermore, the exposed surface of the shielding layer close to the light-emitting area has other rough structures.

Furthermore, the other rough structures are nanoparticles, where the average diameter of the nanoparticles is not greater than 1 micrometer.

Furthermore, the shielding layer is capable of shielding light and absorbing light; the reflectivity of the surface of the shielding layer is not higher than 0.5%.

Furthermore, the material of the shielding layer is one or more of the following: photoresist, gray paste, inorganic anti-reflective material, or black inorganic material.

Based on the aforementioned micro-display chip, the second aspect of the present disclosure provides a display panel, which includes the aforementioned micro-display chip.

Furthermore, the display panel further includes:

a connection line including opposed first connection end and second connection end, and the first connection end of the connection line is electrically connected with the micro-display chip; and

a connector, the second connection end of the connection line is electrically connected with the connector, and the connector is connected with external compatible devices.

The third aspect of the present disclosure provides a manufacturing method for the aforementioned micro-display chip, which includes:

forming a metal layer on a drive backplane;

forming a micro-LED array and a micro-lens array on the surface of the metal layer to form a light-emitting area of the micro-display chip, where the edge of the micro-LED array does not extend beyond the edge of the metal layer;

forming a shielding layer or a package layer on the surface of the metal layer not covered by the micro-LED array, where if a package layer is formed, then the package layer completely covers the surface of the metal layer, and if a shielding layer is formed, then the shielding layer covers at least a part of the surface of the metal layer; and

forming a package layer on the surface of the shielding layer and/or the surface of the metal layer not covered by the shielding layer, where the surface of the package layer includes a plurality of rough structures.

Furthermore, forming the shielding layer includes:

forming a light-absorbing material layer on the metal layer using at least one coating and exposure development process; and

exposing and developing the light-absorbing material layer based on a mask, removing the light-absorbing material film formed on the light-emitting area.

Furthermore, forming the package layer includes:

forming a cured material layer on the shielding layer;

performing roughening treatment on the surface of the cured material layer to make the surface of the shielding layer have a plurality of rough structures.

Furthermore, the roughening treatment includes:

bombarding the surface of the cured material layer using a plasma treatment device to make the surface of the package layer have a plurality of rough structures.

Furthermore, the gas used for bombardment includes one or more of O₂ and Ar.

The present disclosure provides a micro-display chip including a shielding layer and a package layer, and the surface of the package layer is etched and roughened to reduce its reflectivity, so that the light emitted from the light-emitting area is diffusely reflected after being reflected by the outside and reaching the surface of the package area, which can effectively reduce the re-reflection of full-band light and improve the quality of image display. Furthermore, surface roughening treatment can optimize the demolding marks formed on the micro-display chip package body.

### BRIEF DESCRIPTION OF THE DRAWINGS

To further explain the above and other advantages and features of various embodiments of the present disclosure, a more specific description of various embodiments of the present disclosure will be provided with reference to the accompanying drawings. It can be appreciated that these accompanying drawings depict only typical embodiments of the present disclosure, and therefore will not be construed as limiting their scope. In the accompanying drawings, identical or corresponding parts will be indicated by the same or similar reference numerals for the sake of clarity.

FIG. 1 illustrates a structural schematic diagram of an existing micro-LED micro-display panel;

FIG. 2 illustrates the light propagation path schematic diagram of the micro-LED micro-display panel applied to AR glasses in the embodiment shown in FIG. 1;

FIG. 3 illustrates a top view structural schematic diagram of the metal layer of a micro-LED display chip according to an embodiment of the present disclosure;

FIG. 4 illustrates a cross-sectional view schematic diagram along line A-A of the embodiment shown in FIG. 3;

FIG. 5 illustrates a local structural schematic diagram of the light-emitting area of a micro-LED display chip according to an embodiment of the present disclosure;

FIG. 6 illustrates a top view structural schematic diagram of a micro-display panel according to an embodiment of the present disclosure;

FIG. 7 illustrates a cross-sectional view schematic diagram along line A-A of the embodiment shown in FIG. 6;

FIGS. 8A to FIG. 8E illustrate top view structural schematic diagrams of a micro-display panel according to different embodiments of the present disclosure;

FIGS. 9A to FIG. 9E illustrate cross-sectional view schematic diagrams along line A-A of the embodiments shown in FIGS. 8A to FIG. 8E, respectively;

FIG. 10 illustrates a flowchart schematic diagram of a manufacturing method for a micro-display chip according to an embodiment of the present disclosure;

FIGS. 11A to FIG. 11D illustrate process flow schematic diagrams of a manufacturing method for a micro-display chip according to an embodiment of the present disclosure;

FIG. 12 illustrates a flowchart schematic diagram of a manufacturing method for a micro-display chip according to yet another embodiment of the present disclosure; and

FIGS. 13A to FIG. 13E illustrate process flow schematic diagrams of a manufacturing method for a micro-display chip according to yet another embodiment of the present disclosure.

### DESCRIPTION OF THE EMBODIMENTS

In the following description, the present disclosure is described with reference to various embodiments. However, those skilled in the art will recognize that various embodiments can be implemented without one or more specific details or with other alternative and/or additional methods, materials, or components. In other situations, well-known structures, materials, or operations are not shown or described in detail so as not to obscure the inventive point of the present disclosure. Similarly, for the purpose of explanation, specific quantities, materials, and configurations are set forth in order to provide a comprehensive understanding of embodiments of the present disclosure. However, the present disclosure is not limited to these particular details. Furthermore, it should be appreciated that the embodiments illustrated in the accompanying drawings are illustrative representations and are not necessarily drawn to the correct scale.

In the present description, a reference to "an embodiment" or "the embodiment" means that particular feature, structure or characteristic described in connection with the embodiment are included in at least one embodiment of the present disclosure. The phrase "in one embodiment" appearing throughout this description may not necessarily all refer to the same embodiment.

In the description of the present disclosure, it should be understood that the terms such as "above", "below", "top surface", "bottom surface", etc. indicate orientation or positional relationships based on the orientation or positional relationships shown in the accompanying drawings, only for the convenience of describing the present disclosure and simplifying the description, and do not indicate or imply that the positions or elements referred to must have specific orientations, be constructed and operated in specific orientations, and therefore cannot be understood as limitations of the present disclosure. Furthermore, the terms "first" and "second" are only used to distinguish an entity or operation from another entity or operation, and do not require or imply any actual relationship, order, or relative importance between these entities or operations.

It should be noted that the embodiments of the present disclosure describe the process steps in a specific order, however, this is only for the purpose of illustrating the specific embodiment, rather than limiting the order of the steps. On the contrary, in different embodiments of the present disclosure, the order of the steps can be modified according to the adjustment of the process.

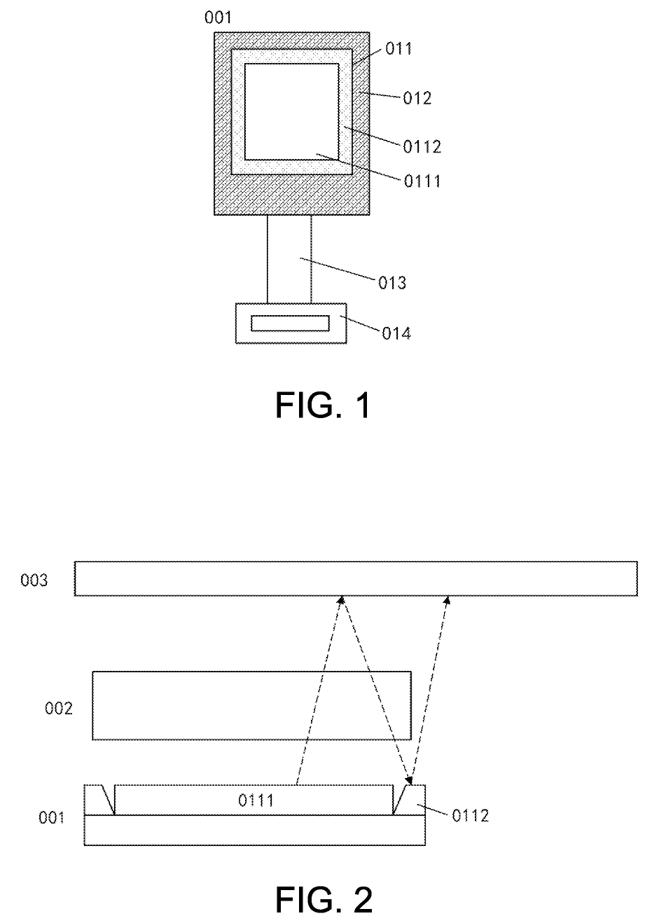

As shown in FIG. 1, when the micro-LED micro-display panel is applied to corresponding products, light emitted from its light-emitting area reaches the optical waveguide lens, a part of this light will be reflected back to the non-light-emitting area of the micro-display panel and then be reflected again into the optical waveguide lens, forming ghost images. In order to solve this problem, a shielding layer with an uneven surface can be formed on the metal layer surface of the non-light-emitting area, so that the reflected light produces diffuse reflection and reduces the re-reflection of the full-band light. However, when forming a micro-display panel, it is necessary to further surround and package the micro-display chip, specifically by molding, and the formed package layer may also reflect light, thereby affecting the display effect.

In order to solve this problem, the present disclosure further etches and roughens the surface of the formed package layer after demolding is completed, on the one hand, it can further reduce the reflectivity of the package layer, and on the other hand, it can repair the damage to and abnormalities of the shielding layer caused during the package process.

The technical solutions of the present disclosure are further described below in conjunction with the accompanying drawings of the embodiments.

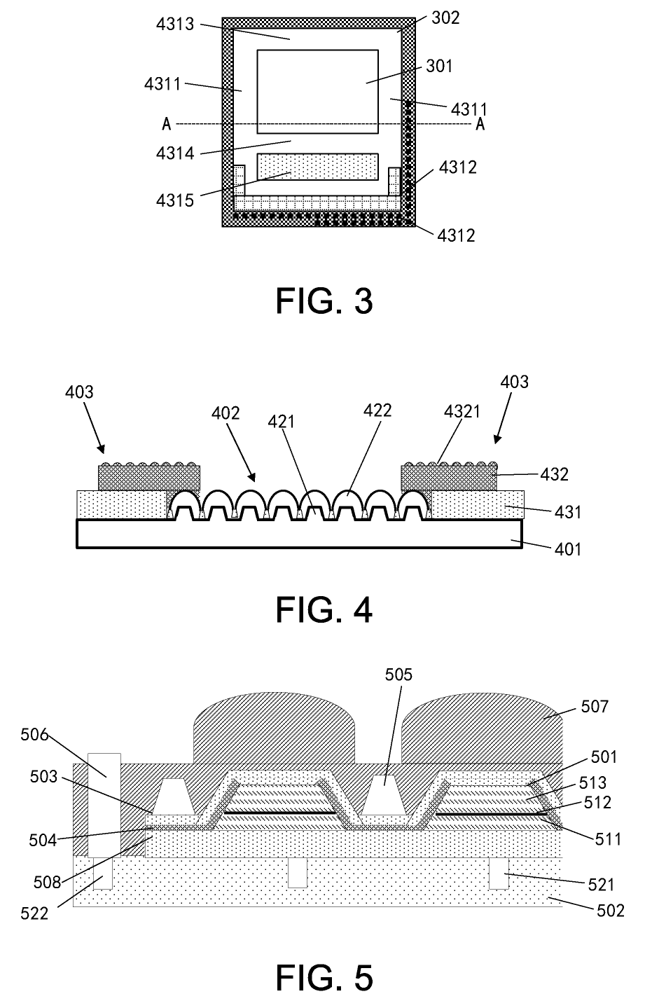

FIG. 3 illustrates a top view structural schematic diagram of the metal layer of a micro-LED display chip according to an embodiment of the present disclosure. FIG. 4 illustrates a cross-sectional view schematic diagram along line A-A of a micro-LED display chip according to an embodiment of the present disclosure. As shown in the figure, a micro-LED display chip includes a light-emitting area 301 and a non-light-emitting area 302 arranged around the light-emitting area 301.

As shown in the figure, in one embodiment of the present disclosure, the micro-LED display chip includes a drive backplane 401, and a light-emitting area 402 and a non-light-emitting area 403 formed on the drive backplane 401. The light-emitting area 402 includes a micro-LED array, the micro-LED array includes a plurality of micro-LEDs 421, and each micro-LED can form at least a part of a pixel element on the micro-LED chip.

In embodiments of the present disclosure, the size of each micro-LED chip does not exceed 1 centimeter, preferably not exceeding 20 micrometers. The micro-LED structures are formed in the form of an array in the micro-LED chip, with resolutions such as 720*480, 640*480, 1920*1080, 1280*720, 2K, or 4K. The diameters of the micro-LED structures are in the nanometer-level, for example, 20 nm to 100 nm.

In some embodiments of the present disclosure, the micro-LED array may include a single-layer micro-LED structure. In some embodiments of the present disclosure, the micro-LED array may include a multi-layer vertically stacked micro-LED structure.

In some embodiments of the present disclosure, the micro-LED array may include blue micro-LEDs. In some embodiments of the present disclosure, the pitch of the micro-LED array, i.e., the minimum center-to-center distance between micro-LEDs may range from approximately 2 micrometers to approximately 50 micrometers. In some embodiments, the number of pixels on a micro-LED chip may range from thousands to millions.

In one embodiment of the present disclosure, the drive backplane may be electrically connected with each micro-LED in the micro-LED array through individual metal interconnections. In some embodiments, each micro-LED may be individually electrically controlled by the drive backplane. In some embodiments, the drive backplane may be electrically connected with the electrodes of the micro-LED chips through metal interconnections. In some embodiments, a dielectric layer may be formed in the gaps between the micro-LEDs. In some embodiments, the dielectric layer may also be formed in the gaps between the interconnections.

FIG. 5 illustrates a local structural schematic diagram of the light-emitting area of a micro-LED display chip according to an embodiment of the present disclosure. As shown in FIG. 5, in one embodiment of the present disclosure, each micro-LED in the micro-LED array may include a micrometer-level light-emitting mesa structure 501. In one embodiment of the present disclosure, the light-emitting mesa structure may include, from bottom to top, a first type epitaxial layer 511, a light-emitting layer 512, and a second type epitaxial layer 513. That is to say, in the three-layer structure, the first type epitaxial layer 511 is closest to the drive backplane 502; the light-emitting layer 512 is located above the first type epitaxial layer 511 and further away from the drive backplane 502; and the second type epitaxial layer 513 is located above the light-emitting layer 512 and furthest away from the drive backplane 502. In some embodiments, the light-emitting layer 512 is formed by multiple stacked quantum-well layers, particularly superlattice-stacked quantum-well layers. Preferably, the superlattice-stacked quantum-well layers include multiple pairs of quantum-well layers stacked with quantum barrier layers. In one embodiment of the present disclosure, the quantum-well layer is an InGaN/GaN multi-quantum-well layer or an InGaN/AlGaN multi-quantum-well layer or an InGaAs/AlGaAs multi-quantum-well layer. In one embodiment of the present disclosure, the light-emitting layer also includes an electron barrier layer, and the electron barrier layer is arranged on a first side of the light-emitting layer, and the first side refers to the side along which electrons migrate out of the light-emitting layer.

In one embodiment of the present disclosure, the first type epitaxial layer 511 is a semiconductor material having a first conductivity type and includes a plurality of semiconductor layers. The primary base material of the first type epitaxial layer 511 may be, but is not limited to, at least two or more elements of Ga, N, As, P, In, and Al. The first type epitaxial layer 511 includes, but is not limited to, a waveguide layer, a confinement layer, a transition layer, and a window layer; furthermore, an ohmic contact layer may be formed beneath the window layer. In some embodiments, the second type epitaxial layer 513 is a semiconductor material having a second conductivity type and includes a plurality of semiconductor layers. The primary base material of the second type epitaxial layer 513 may be, but is not limited to, at least two or more elements of Ga, N, As, P, In, and Al. Furthermore, the second type epitaxial layer 513 may include, from top to bottom, but is not limited to, a confinement layer and a waveguide layer; furthermore, in some embodiments, an ohmic contact layer may be formed on the confinement layer. In one embodiment of the present disclosure, the first-type epitaxial layer 511 is an N-type GaN layer or an N-type AlGaN layer, and the second type epitaxial layer 513 is a P-type GaN layer or a P-type AlGaN layer, that is, the material of the second type epitaxial layer 513 may be a material layer including at least two or more elements of Ga, N, As, Al, In, and P, and the first type epitaxial layer 511 may be a material layer of the first conductivity type including at least two or more of Ga, N, As, Al, In, and P. In yet another embodiment of the present disclosure, the first type epitaxial layer 511 may also be a p-type GaN layer or a p-type AlGaN layer, and the second type epitaxial layer 513 is an n-type GaN layer or an n-type AlGaN layer. In embodiments of the present disclosure, the semiconductor light-emitting mesa 501 is a step shape or trapezoidal shape.

In one embodiment of the present disclosure, a top conductive layer 503 may be formed on the top surface of the micro-LED array. In one embodiment of the present disclosure, the top conductive layer 503 may be shared by all micro-LEDs in the micro-LED array. In one embodiment of the present disclosure, the top conductive layer 503 is arranged above the micro-LED array and in contact with and covering the top of each light-emitting mesa 501, and electrically connected with the second type epitaxial layer 513 of the light-emitting mesa 501, thereby series-connecting the second type epitaxial layers 513 of the respective semiconductor light-emitting mesas 501, which is a transparent conductive layer.

In one embodiment of the present disclosure, the micro-LED array further includes a passivation isolation layer 504. The passivation isolation layer 504 covers the surface and side surface of the light-emitting mesa 501 but exposes at least a part of the surface of the second type epitaxial layer 513, and the top conductive layer 503 is arranged on the surface of the passivation isolation layer 504. In one embodiment of the present disclosure, the passivation isolation layer 504 may be formed by depositing SiO₂ film layer by CVD or Al₂O₃ film layer by ALD to effectively reduce chip leakage current. In some embodiments of the present disclosure, the passivation isolation layer 504 covers only the side surface of the light-emitting mesa 501, but not covers the top surface of the light-emitting mesa 501, and the highest point of the passivation isolation layer 504 is flush with the top surface of the light-emitting mesa 501, and in these embodiments, the continuous top conductive layer 503 covering the top surface of the light-emitting mesa 501 forms a horizontal or substantially horizontal planar surface. In some embodiments of the present disclosure, the passivation isolation layer 504 not only covers the side surface of the light-emitting mesa 501, but also covers the edge portion of the top surface of the light-emitting mesa 501, therefore, a protrusion exists at the top edge of the light-emitting mesa 501, such that the continuous top conductive layer 503 covering it similarly forms a protrusion at the top edge of the light-emitting mesa 501.

As previously described, there are isolations between the pixel points formed by each light-emitting mesa, and a second electrode 505 is arranged at these isolations, and the second electrode 505 is arranged on the surface of the top conductive layer 503. In one embodiment of the present disclosure, the second electrode 505 is a ring-shaped reflective electrode arranged around the light-emitting mesa 501, and it is formed through magnetron sputtering or evaporation, and its material may be, for example, Al or Al alloy metal as the sidewall reflective mirror, and the electrode stacked metal may be metal materials such as Ni, Al, Ti, Ni, Pt, Au, etc. In one embodiment of the present disclosure, the second electrodes are connected with each other. In some embodiments of the present disclosure, deep trenches are arranged at the isolations between adjacent light-emitting mesas, and the deep trenches pass through the micro-LED array, and the second electrodes 505 are arranged at the deep trenches. In some embodiments of the present disclosure, no deep trench is formed at the isolations between adjacent light-emitting mesas, but a passivation isolation layer and a top conductive layer are directly formed, consequently, the surface of the top conductive layer between adjacent light-emitting mesas is a horizontal or substantially horizontal plane, and the second electrode is formed here, and its morphology interface is trapezoidal or approximately trapezoidal, the trapezoid may be either a normally arranged trapezoid or an upside-down arranged trapezoid, and the surface of the second electrode is not higher than the highest point of the continuous top conductive layer.

In one embodiment of the present disclosure, the micro-LED array is bonded to the drive backplane 502 through the metal bonding layer 508 and is electrically connected with the IC copper pillars on the drive backplane 502. In one embodiment of the present disclosure, the IC copper pillars include first IC copper pillars 521 and second IC copper pillars 522, where the first IC copper pillars 521 are electrically connected in one-to-one correspondence with the first epitaxial layer 511 of the semiconductor light-emitting module. The second IC copper pillars 522 are electrically connected with the first electrode 506. In one embodiment of the present disclosure, the polarity of the first electrode 506 is opposite to that of the second electrode 505. In one embodiment of the present disclosure, each semiconductor light-emitting module has a common first electrode. The first electrode 506 may, for example, be a P-type electrode or an anode electrode, and the second electrode 505 is an electrode with polarity opposite to that of the first electrode 506, such as an N-type electrode or a cathode electrode. In one embodiment of the present disclosure, the first and second electrodes and their connection components may be made of materials such as graphene, ITO, aluminum-doped zinc oxide (AZO), or fluorine-doped tin oxide (FTO), or any combination of the above materials. In another embodiment of the present disclosure, the first and second electrodes and their connection components may be made of non-transparent or transparent conductive materials, such as indium tin oxide (ITO).

As shown in the figure, in one embodiment of the present disclosure, the light-emitting area also includes a micro-lens array. The micro-lens array is arranged above the micro-LED array, where at least one micro-lens 507 is provided on the surface of the conductive layer at the top of the micro-LED, and the horizontal contour of the micro-lens is larger than the maximum horizontal contour of the micro-LED. The microlens primarily serves to converge and/or collimate light, for example, by adjusting parameters such as the thickness and curvature of the microlens, etc., the focal point of the microlens can be located in the light-emitting mesa of the micro-LED.

As shown in the figure, in one embodiment of the present disclosure, microlenses in the microlens array correspond one-to-one with the light-emitting mesas. In some embodiments of the present disclosure, adjacent microlenses have gaps between them and their bottoms are connected with each other. The bottom of the gap may be lower than the top of the light-emitting mesa of the micro-LED, or lower than the bottom of the light-emitting layer of the light-emitting mesa, or located above the second electrode 505, or located between two peaks of the second electrode. In other embodiments of the present disclosure, adjacent microlenses are completely connected, but there is a gap in the connection portion, and the bottom of the connection portion may be lower than the top of the light-emitting mesa of the micro-LED, or lower than the bottom of the light-emitting layer of the light-emitting mesa, or located above the second electrode, or located between two peaks of the second electrode. Furthermore, in one embodiment of the present disclosure, the microlens has an air gap inside it.

In one embodiment of the present disclosure, the microlens may be formed through a plurality of deposition processes, in the process of forming the microlens, a SiO₂ film layer needs to be deposited first, followed by ion etching, and the microlens is formed at positions on the surface of the passivation isolation layer corresponding to each light-emitting mesa.

As shown in FIG. 4, the non-light-emitting area 403 surrounds and encloses the light-emitting area 402, and the non-light-emitting area 403 includes, a metal layer 431 and a shielding layer 432 stacked sequentially from bottom to top. In some embodiments of the present disclosure, the non-light-emitting area 403 further includes a package layer 433.

The metal layer 431 is formed on the surface of the drive backplane 401, and located at the periphery of the micro-LED array, and at least a part of it is electrically connected with the micro-LED array.

In one embodiment of the present disclosure, as shown in FIG. 3, in the direction from the micro-LED array toward the chip edge, the metal layer 431 sequentially includes a continuous metal area 4311 and a plurality of metal pads 4312, where the continuous metal area 4311 is connected with the micro-LED array, and the plurality of metal pads 4312 each form one-dimensional or two-dimensional arrays in each direction around the continuous metal area 4311. In one embodiment of the present disclosure, the metal pads 4312 may be used for wire bonding. In one embodiment of the present disclosure, as shown in FIG. 3, the light-emitting area, specifically the micro-LED array, is located eccentrically relative to the continuous metal area 4311. In one embodiment of the present disclosure, the continuous metal area 4311 has a first area 4313 and a second area 4314 arranged opposed to each other, where the width of the first area 4313 is less than the width of the second area 4314. As shown in the figure, in one embodiment of the present disclosure, the second area 4314 includes a marking area 4315 in the second area 4314, where the metal pads 4312 are located on at least the outer side of the second area 4314.

The shielding layer 432 is formed on the surface of or above the metal layer 431, and covers at least a part of the surface of the metal layer 431. In one embodiment of the present disclosure, the shielding layer 432 is located on the surface of or above the continuous metal area 4311, specifically, the shielding layer 432 is formed on the surface of or above the first area 4313 of the metal layer 431 and on the surface of or above a part of the second area 4314. In one embodiment of the present disclosure, the shielding layer 432 is also located on the surface of or above a part of the plurality of metal pads 4312. Specifically, the shielding layer 432 exposes the plurality of metal pads 4312 close to the chip edge, or the shielding layer 432 is located on or over the entire metal pads 4312.

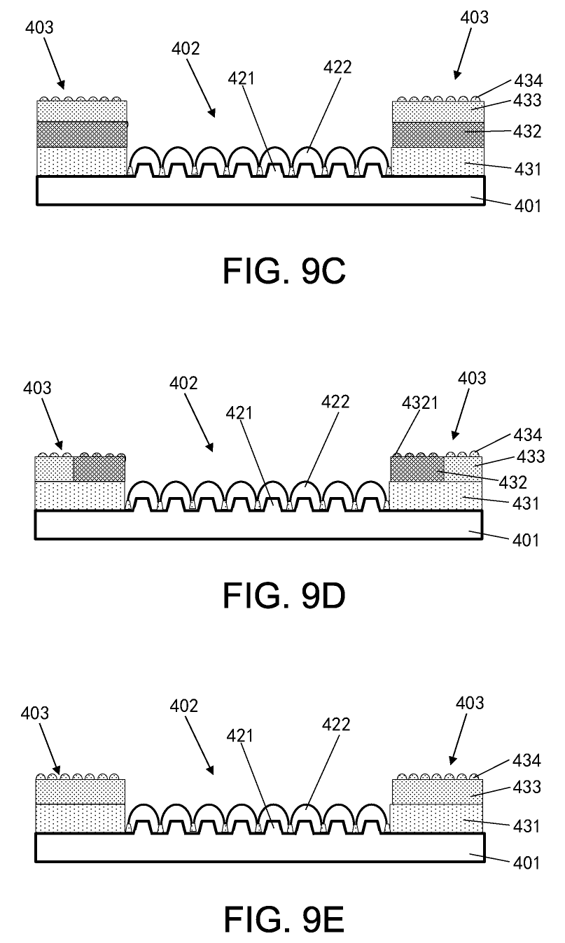

In some embodiments of the present disclosure, the shielding layer 432 also covers a part of the light-emitting area, for example, it covers the surface or top of the edges of the micro-LED array, thereby shielding a part of the micro-LEDs at the edges of the micro-LED array. For example, in the embodiment shown in FIG. 4, the outer edge of the shielding layer 432 is flush with the outer edge of the metal layer 431, and the inner edge of the shielding layer 432 is located above the micro-LED array, for example, between the outermost first ring and second ring of micro-LEDs of the micro-LED array, i.e., the shielding layer 432 completely covers the surface of the metal layer 431, meanwhile, it also covers a part of the micro-LEDs at the edge of the micro-LED array. In other embodiments of the present disclosure, the shielding layer 432 may not cover the light-emitting area, i.e., the inner edge of the shielding layer 432 does not extend beyond the inner edge of the non-light-emitting area, as shown in FIGS. 9A and FIG. 9C. Meanwhile, the outer edge of the shielding layer 432 may not extend beyond the outer edge of the metal layer 431, i.e., the shielding layer 432 does not fully cover the metal layer 431, as shown in FIGS. 9B and FIG. 9D.

In one embodiment of the present disclosure, the shielding layer 432 is formed by the following steps:

Using at least one coating and exposure development process, a light-absorbing material layer is formed on the surface of the metal layer 431, specifically, for example, the light-absorbing material film is formed on the metal layer 431 and the light-emitting area; and

The light-absorbing material film is exposed and developed based on a mask, and the light-absorbing material film formed on the light-emitting area is removed, and a shielding layer 432 is formed.

In one embodiment of the present disclosure, a part of the light-absorbing material film at the edge of the light-emitting area may also be retained. In some embodiments of the present disclosure, during the formation of the shielding layer, multiple coatings and exposure developments can be used to increase the thickness of the light-absorbing layer, for example, when the thickness of the deposited light-absorbing material film reaches approximately 8000 angstroms, the light-absorbing material film is exposed and developed, and the light-absorbing material film formed on the light-emitting area is removed; the aforementioned coating and exposure development steps are repeated until the thickness of the light-absorbing layer 432 is approximately 24,000 angstroms.

In one embodiment of the present disclosure, the material of the light-absorbing material film may be photoresist, gray resist, inorganic anti-reflective material (e.g., ZnO-SiO₂), or black inorganic material (e.g., carbon nanotubes, etc.).

In one embodiment of the present disclosure, at least a part of the surface of the shielding layer 432 has first rough structures 4321, and the first rough structures 4321 are nanoparticles, and the average diameter of the nanoparticles does not greater than 1 micrometer.

In one embodiment of the present disclosure, the reflectivity of the surface of the shielding layer 432 is not higher than 0.5%, so that the shielding layer 432 can block and absorb light.

In one embodiment of the present disclosure, the shielding layer may also not be arranged, as shown in FIG. 9E.

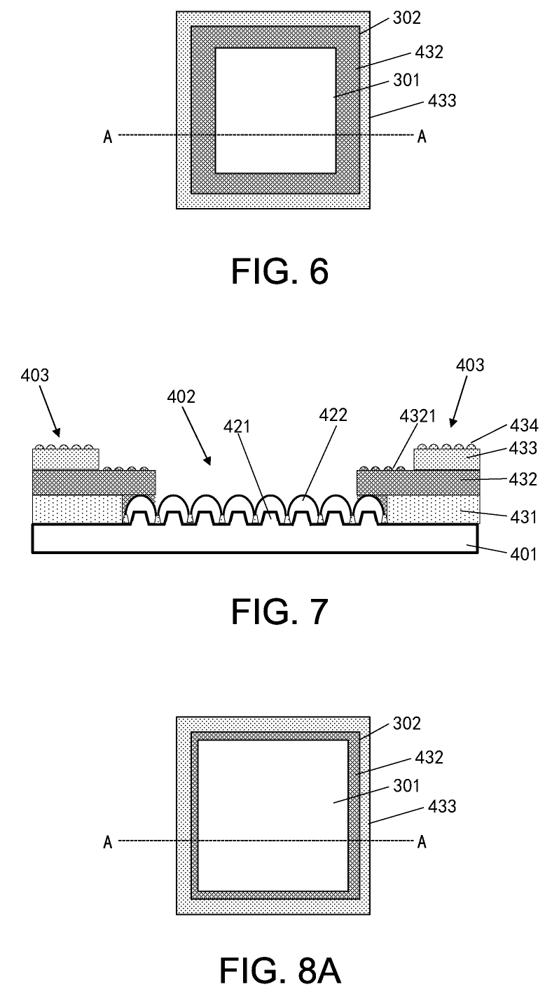

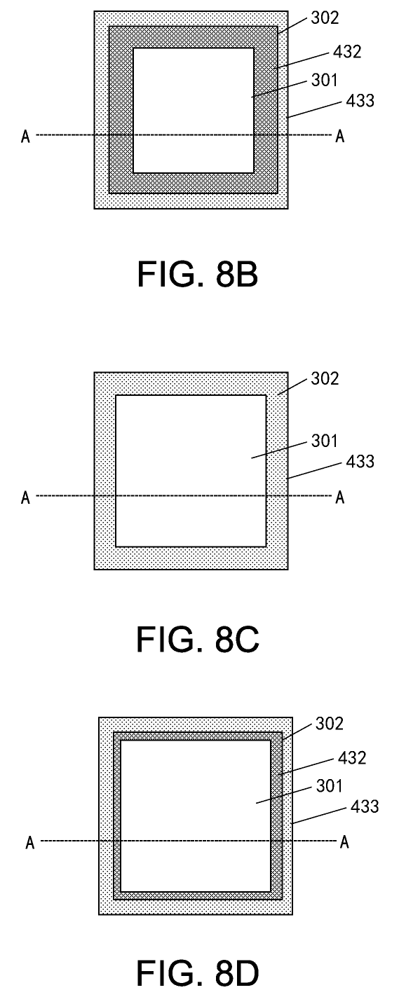

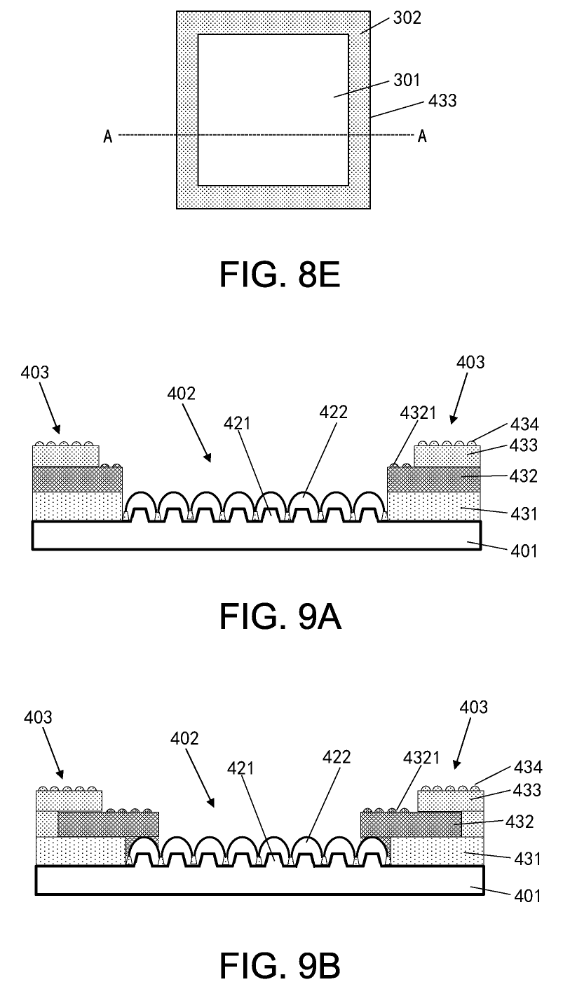

As shown in FIG. 6 and FIG. 7, in one embodiment of the present disclosure, a micro-display chip further includes a package layer 433 on the non-light-emitting area based on the aforementioned micro-LED display chip. The package layer 433 is formed on the uncovered surface of the shielding layer 432 and/or the metal layer 431, which covers at least a part of the surface of the shielding layer 432, and the surface of the package layer 433 includes a plurality of rough structures 434. As shown in FIG. 6 and FIG. 9A, in one embodiment of the present disclosure, the outer edge of the package layer 433 is flush with the outer edge of the shielding layer 432, and the inner edge of the package layer 433 does not extend beyond the inner edge of the shielding layer, i.e., a part of the surface of the shielding layer 432 close to the light-emitting area is not covered. In other embodiments of the present disclosure, the package layer 433 may completely cover the shielding layer 432, as shown in FIG. 9C. When the shielding layer 432 does not completely cover the metal layer 431, the package layer 433 may be formed on the uncovered surfaces of the shielding layer 432 and the metal layer 431, where the outer edge of the package layer 433 is flush with the outer edge of the metal layer 431, as shown in FIG. 9B. The package layer 433 may also be directly formed on the uncovered surface of the metal layer 431, where the outer edge of the package layer 433 is flush with the outer edge of the metal layer 431, meanwhile, the package layer 433 has the same height as the shielding layer 432, as shown in FIG. 9D. It should be noted that "inner side" refers to the side closer to the light-emitting area, while "outer side" refers to the side farther away from the light-emitting area.

In one embodiment of the present disclosure, the package layer 433 is formed by injection molding, so that it needs to be demolded, demolding marks may be formed during demolding, causing damage. In order to optimize this damage, in embodiments of the present disclosure, the surfaces of the package layer 433 and the exposed shielding layer 432 are etched and roughened. In one embodiment of the present disclosure, the package layer 433 is made of a solid plastic material, and its basic component may be, for example, epoxy resin. The reflectivity of the package layer 433 is approximately 3% to 4%.

As shown in FIG. 6, in one embodiment of the present disclosure, the surface of the package layer 433 includes a plurality of rough structures 434. The plurality of rough structures 434 are nanoparticles, and the average diameter of them is not greater than 1 micrometer, so that a dense and rough nanostructure is formed, such that the surfaces of the package layer 433 and the exposed shielding layer 432 are in a matte state to reduce their surface reflectivity, in one embodiment of the present disclosure, the reflectivity of the molded layer after roughening treatment can be reduced to 0.5% or less, so that the optical reflection light is effectively reduced. In one embodiment of the present disclosure, the maximum height and/or transverse dimension of the rough structures are in the range of 1 to 100 nanometers. In some embodiments of the present disclosure, the roughened portion is a conical structure; where the bottom width of the roughened portion is 50 to 200 nanometers, and the height of the roughened portion is 50 to 300 nanometers.

In one embodiment of the present disclosure, the rough structures are formed through surface roughening treatment. Specifically, it is formed by bombarding the surfaces of the package layer 433 and the exposed shielding layer 432 using plasma processing equipment such as ICP/RIE/Plasma, etc. In one embodiment of the present disclosure, during the bombardment process, the gas used may be O₂, Ar, or a mixed gas. In embodiments of the present disclosure, the bombardment time is not limited, and the power is not limited. The morphology of the plurality of rough structures formed by this roughening process is different, i.e., the plurality of the rough structures have irregular dimensions, which can effectively enhance the effect of diffuse reflection, further reduce the re-reflection of full-band light, and improve the display quality of the picture.

In one embodiment of the present disclosure, before forming the package layer 433, the shielding layer 432 may undergo a surface roughening treatment to first form a plurality of second rough structures 4321 on the surface of the shielding layer 432. The second rough structures may be formed, for example, using an ion etching process. Although surface roughening is performed again after forming the package layer 433 to form first rough structures 434 on the surface of the package layer 433. The rough structures on the surface of the exposed shielding layer 432 can be understood as a superposition of the first rough structures and the second rough structures, and the overall morphology may be different from the rough structures on the surface of the package layer 433.

In yet another embodiment of the present disclosure, before forming the package layer 433, the shielding layer 432 is not subjected to surface roughening treatment, instead, after forming the package layer 433, the surfaces of the package layer 433 and the exposed shielding layer 432 are roughened simultaneously.

Based on the micro-display chip described above, the present disclosure further provides a display panel including the aforementioned micro-display chip, a connection line, and a connector. The connection line includes opposed first connection end and second connection end, and the first connection end of the connection line is electrically connected with the micro-display chip, and the second connection end of the connection line is electrically connected with the connector, and the connector is connected with external compatible devices.

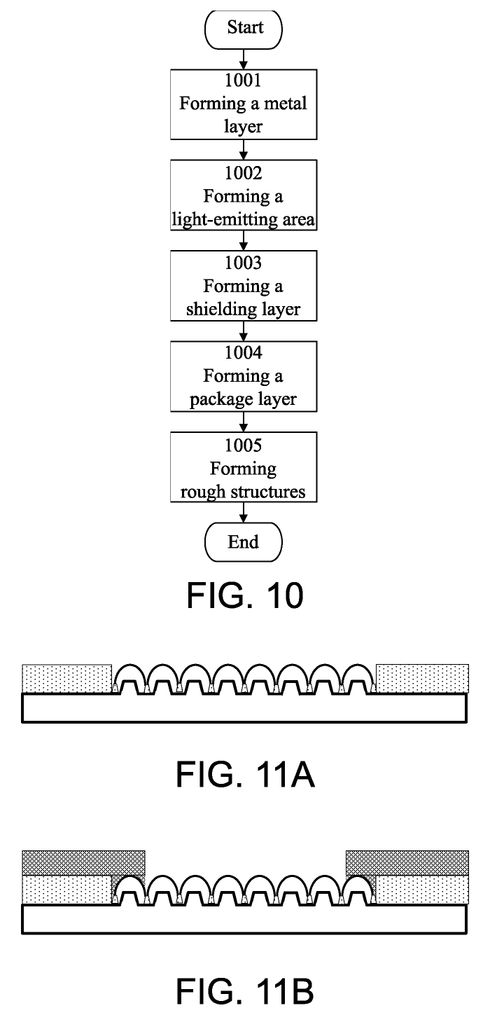

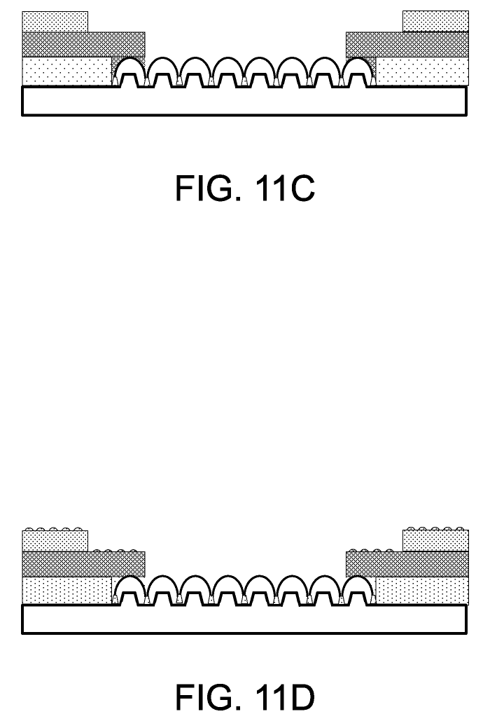

FIG. 10 illustrates a flowchart schematic diagram of a manufacturing method for the micro-display chip described above, meanwhile, FIG. 11A to FIG. 11D illustrate structural schematic diagrams of each step. As shown in the figures, a method for manufacturing a micro-display chip includes:

First, in step 1001, a metal layer is formed. The metal layer is formed on the drive backplane;

Next, in step 1002, as shown in FIG. 11A, a light-emitting area is formed. A micro-LED array and a micro-lens array are formed on the drive backplane, and the micro-LED array is electrically connected with the metal layer to form the light-emitting area of the micro-display chip. Specifically, firstly, a second type epitaxial layer, an electron barrier layer, a multi-layer quantum-well, and a first type epitaxial layer are sequentially deposited on the substrate, then the substrate is thinned to form a semiconductor light-emitting module. Meanwhile, an adhesion layer, a reflective layer, a barrier layer, and a bonding metal are also sequentially deposited on the surface of the first type epitaxial layer. The semiconductor light-emitting module is then bonded to the drive backplane through the bonding metal, such that electrical interconnection is formed between the IC copper pillars on the drive backplane and the semiconductor light-emitting module. In one embodiment of the present disclosure, after chip bonding, the substrate may be ground and thinned to be removed, or removed by laser stripping to further thin the buffer layer structure and facilitate the subsequent formation of PN step structure. In embodiments of the present disclosure, bonding processes may use thermal compression bonding, eutectic bonding, etc. Step etching is subsequently performed, by adjusting the photolithographic morphology, the semiconductor light-emitting module is ion etched to form normally arranged trapezoid structure pixel points, in one embodiment of the present disclosure, the horizontal angles of the normally arranged trapezoid structure pixel points may be, for example, 65 ° to 85 °. Then, a passivation isolation layer is formed on the sidewall and surface of each pixel point, in one embodiment of the present disclosure, the passivation isolation layer is formed by depositing SiO₂ film layer by CVD and/or Al₂O₃ film layer by ALD to reduce the chip leakage rate. After deposition, photolithography etching is performed above the corresponding pixel points to expose at least a part of the surface of the second type semiconductor layer. A top conductive layer is further formed on the surface of the passivation isolation layer to achieve common series connection of the second type epitaxial layers for each pixel point. Ring-shaped reflective electrode is formed at the isolations of each pixel point. In one embodiment of the present disclosure, the ring-shaped reflective electrode is formed using magnetron sputtering or evaporation processes. In one embodiment of the present disclosure, the second electrode uses Al or Al alloy metals as the sidewall reflective mirror, while the electrode stacked metals uses metal materials such as Ni, Al, Ti, Pt, or Au, etc. In one embodiment of the present disclosure, before forming the passivation isolation layer, deep trench etching may also be performed at the isolations of each pixel point, for example, using techniques such as photolithography and IBE inert gas physical etching processes, etc., subsequently, the second electrode is formed in the deep trenches. Thereafter, the first electrode is formed on the drive backplane, and the first electrode is connected with the IC copper pillars to serve as a protective cushion and facilitate subsequent wire bonding. Finally, SiO₂ is deposited and the photolithographic morphology is adjusted to form a microlens. In one embodiment of the present disclosure, the SiO₂ layer, i.e., the first transmission layer, is deposited by PECVD, and the thickness of the film is approximately 2.5 to 3.5 μm, subsequently, by adjusting the photolithographic morphology of the microlens, such as resist thickness, exposure energy, and film hardening temperature, etc., the photolithographic array morphology at the corresponding pixel points is completed, the microlens passivation protective layer SiO₂ material is ion etched to form hemispherical SiO₂ microlens with a lens-like morphology, which can improve the light output efficiency to a certain extent. At this stage, the initial structure of the micro-LED chip is formed, due to the poor step coverage of SiO₂ deposited by PECVD, microcracks tend to form at the deep trenches of the pixel points, which causes the quantum-well light source to form diffuse reflection at these locations, reducing the light extraction efficiency of the microlenses, furthermore, due to the photolithography dimensions and ion etching of the microlenses, the overall microlens curvature radius, lower spacer height, sphere height, and lens sphere width are all slightly undersized and fail to achieve optimal lens conditions, therefore, in some embodiments of the present disclosure, a secondary deposition may be performed to increase the microlens curvature radius, lower spacer height, sphere height, and lens sphere width. In one embodiment of the present disclosure, the film thickness of the secondary SiO₂ deposition is determined according to the film thickness of the preceding microlens SiO₂ deposition and the microlens etching morphology, in one embodiment, the secondary deposition film thickness is preferably 0.2 to 1 μm, and can be deposited in a single or multiple operations. In one embodiment of the present disclosure, the secondary SiO₂ deposition uses a mixed gas of SiH₄ and N₂O, and the ratio of SiH₄ to N₂O is 1:5, meanwhile, the gas flow is controlled at a low level to ensure that the deposition rate is significantly lower than that of the preceding microlens deposition, and the secondary deposition uses high-vacuum process conditions and a high flow of inert N₂ gas to further improve the step coverage effect of the secondary-deposited SiO₂, which is not prone to defects and can even repair the micro defects of the preceding microlens deposition, and a better brightness enhancement effect is obtained and thus the light-emitting area is formed;

Next, in step 1003, as shown in FIG. 11B, a shielding layer is formed. The shielding layer is formed on the surface of the metal layer. The shielding layer can cover a part of the light-emitting area, meanwhile completely or partially covering the metal layer. In one embodiment of the present disclosure, at least one coating and exposure development process is used to form a light-absorbing material layer on the metal layer, subsequently, based on a mask, the light-absorbing material film is exposed and developed, and the light-absorbing material film formed on the light-emitting area is removed.

Next, in step 1004, as shown in FIG. 11C, a package layer is formed. The package layer is formed on the surface of the shielding layer and/or the uncovered metal layer, and the package layer can completely cover the shielding layer, and also can expose a part of the surface of the shielding layer, but the metal layer should be completely covered. In one embodiment of the present disclosure, the package layer is formed by injection molding; and

Finally, in step 1005, as shown in FIG. 11D, rough structures are formed. Etching roughening treatment is performed on the package layer and exposed shielding layer surface. For example, plasma processing equipment such as ICP/RIE/Plasma, etc., is used to bombard the surface of the package layer and exposed shielding layer, and the gas used may be O₂, Ar, or mixed gases, and the bombardment time is not limited, and the power is not limited, so that a dense and rough nanostructure is formed on the surfaces of the package layer and exposed shielding layer, such that the surfaces of the package layer and the exposed shielding layer are in a matte state to reduce the surface reflectivities of the surfaces of the package layer and the exposed shielding layer, the reflectivity can be reduced to 0.5% or less, so that the optical reflection light is reduced. Concurrently, the demolding marks formed by the package body are optimized.

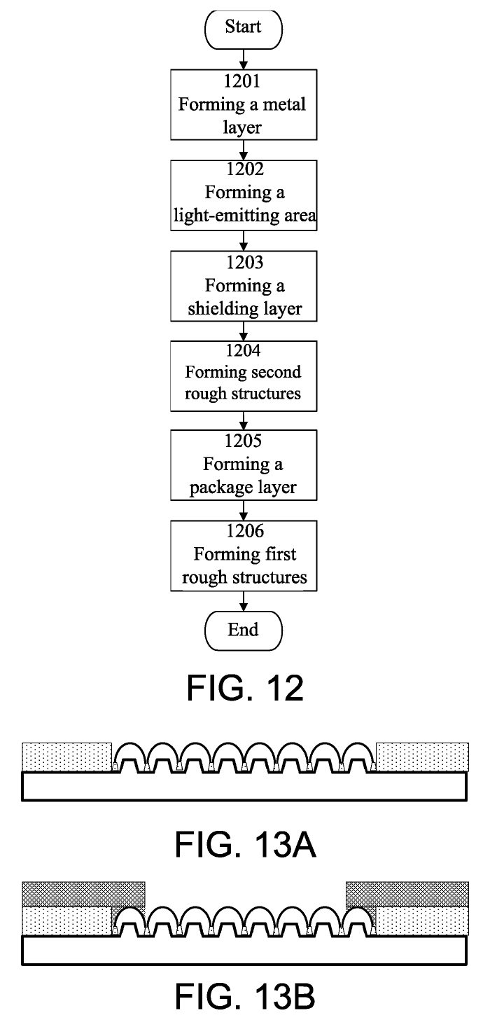

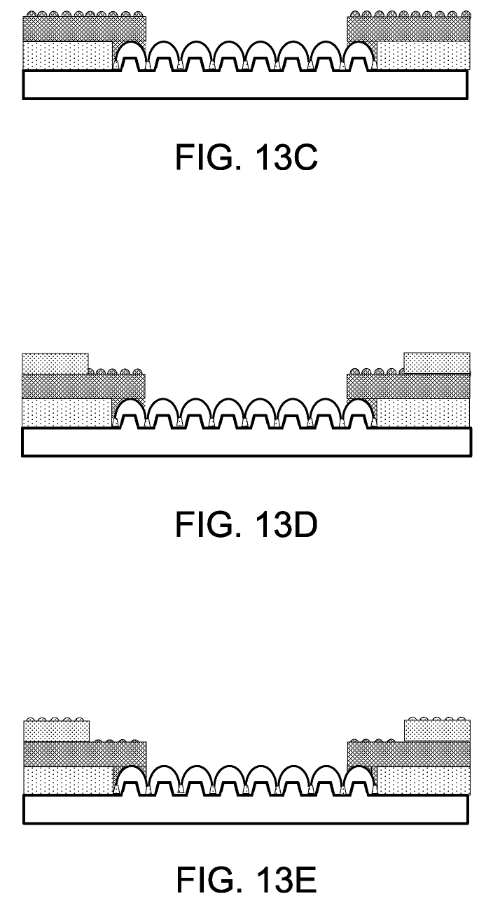

FIG. 12 illustrates a flowchart schematic diagram of a manufacturing method for yet another micro-display chip, meanwhile, FIG. 13A to FIG. 13E illustrate structural schematic diagrams of each step. The manufacturing process of the embodiment shown in FIG. 12 is substantially the same as that of the embodiment shown in FIG. 10, and the difference lies in that, in step 1203, after forming the shielding layer, step 1204 is performed first to form second rough structures on the surface of the shielding layer through processes such as ion etching, etc., then steps 1205 and 1206 are performed to form the package layer and roughening treatment is performed on the package layer and the exposed surface of the shielding layer.

Although the various embodiments of the present disclosure have been described above, however, it should be understood that they are presented only as examples and not as limitations. It will be apparent to those skilled in the art that various combinations, variations and changes can be made thereto without departing from the spirit and scope of the present disclosure. Therefore, the width and scope of the present disclosure disclosed herein should not be limited by the exemplary embodiments disclosed above, but should only be defined based on the accompanying claims and their equivalents.

What is claimed is:

1. A micro-display chip, comprising:
a light-emitting area; and
a non-light-emitting area arranged around the light-emitting area, and the non-light-emitting area comprises a package layer, wherein a surface of the package layer comprises a plurality of rough structures.

2. The micro-display chip according to claim 1, wherein the package layer is made of a solid plastic material.

3. The micro-display chip according to claim 2, wherein the reflectivity of the surface of the package layer having the rough structures is not greater than 0.5%.

4. The micro-display chip according to claim 1, wherein the rough structures are nanoparticles, and the average diameter of the nanoparticles is not greater than 1 micrometer.

5. The micro-display chip according to claim 1, wherein the material of the package layer comprises epoxy resin.

6. The micro-display chip according to claim 1, wherein the periphery of the light-emitting area has a shielding layer, and the package layer is located on a surface of or above the shielding layer.

7. The micro-display chip according to claim 6, wherein a sidewall of the package layer close to the light-emitting area does not extend beyond a sidewall of the shielding layer close to the light-emitting area, so that a surface of the shielding layer close to the light-emitting area is exposed.

8. The micro-display chip according to claim 7, wherein the exposed surface of the shielding layer close to the light-emitting area has other rough structures.

9. The micro-display chip according to claim 8, wherein the other rough structures are nanoparticles, wherein the average diameter of the nanoparticles is not greater than 1 micrometer.

10. The micro-display chip according to claim 8, wherein the shielding layer is capable of shielding light and absorbing light; the reflectivity of the surface of the shielding layer is not higher than 0.5%.

11. The micro-display chip according to claim 6, wherein the material of the shielding layer is one or more of the following: photoresist, gray paste, inorganic anti-reflective material, or black inorganic material.

12. A display panel, comprising the micro-display chip according to claim 1.

13. The display panel according to claim 12, further comprising:
a connection line comprising opposed first connection end and second connection end, and the first connection end of the connection line is electrically connected with the micro-display chip; and
a connector, the second connection end of the connection line is electrically connected with the connector, and the connector is connected with external compatible devices.

14. A method for manufacturing a micro-display chip, comprising the steps of:
forming a metal layer on a drive backplane;
forming at least one micro-LED array and at least one micro-lens array on the surface of the metal layer to form at least one light-emitting area of the micro-display chip, wherein the edge of the at least one micro-LED array does not extend beyond the edge of the metal layer;
forming a shielding layer or a package layer on the surface of the metal layer not covered by the at least one micro-LED array, wherein in a case that a package layer is formed, the package layer completely covers the surface of the metal layer, and in a case that a shielding layer is formed, the shielding layer covers at least a part of the surface of the metal layer; and
forming a package layer on the surface of the shielding layer and/or the surface of the metal layer not covered by the shielding layer, wherein a surface of the package layer comprises a plurality of rough structures.

15. The manufacturing method according to claim 14, wherein forming the shielding layer comprises the steps of:
forming a light-absorbing material layer on the metal layer using at least one coating and exposure development process; and
exposing and developing the light-absorbing material layer based on a mask, removing the light-absorbing material film formed on the light-emitting area.

16. The manufacturing method according to claim 14, wherein forming the package layer comprises the steps of:
forming a cured material layer on the shielding layer;
performing roughening treatment on the surface of the cured material layer to make the surface of the shielding layer have a plurality of rough structures.

17. The manufacturing method according to claim 16, wherein the roughening treatment comprises:
bombarding the surface of the cured material layer using a plasma treatment device to make the surface of the package layer have a plurality of first roughened portions.

18. The manufacturing method according to claim 17, wherein the gas used for bombardment comprises one or more of O₂ and Ar.
